(19) United States
(12) Patent Application Publication
(10) Pub. No.: US 2025/0329539 A1
(43) Pub. Date: Oct. 23, 2025

(54) WAFER PROCESSING METHOD AND CUTTING APPARATUS

(71) Applicant: DISCO CORPORATION, Tokyo (JP)

(72) Inventor: Tomoharu TAKITA, Tokyo (JP)

(21) Appl. No.: 19/081,759

(22) Filed: Mar. 17, 2025

(30) Foreign Application Priority Data
Apr. 18, 2024 (JP) 2024-067389

(51) Int. Cl. H01L 21/304; H01L 21/02; H01L 21/67

(52) U.S. Cl. CPC H01L 21/3043; H01L 21/02021; H01L 21/67092

(57) ABSTRACT

A wafer processing method is a method for annularly cutting a wafer along an outer periphery of the wafer with a cutting blade, and the method includes annularly cutting the wafer with the cutting blade along the outer periphery of the wafer while supplying a cutting fluid to the wafer, and cutting the wafer by changing a position of the cutting blade in a radial direction of the wafer, in which an amount of the cutting fluid supplied during cutting of a position where the cutting blade overlaps an outer peripheral edge of the wafer is set smaller than an amount of the cutting fluid supplied during cutting of a position where the cutting blade does not overlap the outer peripheral edge of the wafer.

### CROSS-REFERENCE TO RELATED APPLICATION(S)

The present application claims priority to and incorporates by reference the entire contents of Japanese Patent Application No. 2024-067389 filed in Japan on Apr. 18, 2024.

### BACKGROUND

The present invention relates to a wafer processing method and a cutting apparatus, for cutting a wafer annularly along the outer peripheral edge of the wafer with a cutting blade.

When so-called edge trimming process is performed on a wafer, a cutting fluid is supplied to the wafer in order to prevent adhesion of cutting chips to the wafer and to cool processing heat generated by cutting (i.e., see JP 2013-225612 A).

In the conventional processing method disclosed in JP 2013-225612 A and the like, when it is desired to remove an annular area having a predetermined width from the outer peripheral edge of the wafer toward the center of the wafer, annular cutting is performed a plurality of times by changing the position of a cutting blade in a radial direction of the wafer, or spiral cutting is performed by the cutting blade.

However, in the conventional processing method disclosed in JP 2013-225612 A and the like, when the cutting blade cuts the outermost periphery of the wafer, the cutting fluid is likely to enter under the lower surface side of the wafer, and when the cutting fluid enters under the lower surface side of the wafer, the wafer is made unstable during cutting, and the processing quality may deteriorate. Therefore, improvement is earnestly desired.

### SUMMARY

A wafer processing method according to one aspect of the present disclosure is for annularly cutting a wafer along an outer periphery of the wafer with a cutting blade, and includes annularly cutting the wafer with the cutting blade along the outer periphery of the wafer while supplying a cutting fluid to the wafer, and cutting the wafer by changing a position of the cutting blade in a radial direction of the wafer. An amount of the cutting fluid supplied during cutting of a position where the cutting blade overlaps an outer peripheral edge of the wafer is set smaller than an amount of the cutting fluid supplied during cutting of a position where the cutting blade does not overlap the outer peripheral edge of the wafer.

A cutting apparatus according to another aspect of the present disclosure includes: a holding table that holds a wafer; a cutting blade that annularly cuts the wafer along an outer periphery of the wafer held by the holding table; and a cutting fluid supply nozzle that supplies a cutting fluid to the wafer to be cut with the cutting blade. The wafer held by the holding table is annularly cut along the outer periphery of the wafer with the cutting blade while supplying the cutting fluid to the wafer from the cutting fluid supply nozzle, and the wafer is cut by changing a position of the cutting blade in a radial direction of the wafer, and an amount of the cutting fluid supplied during cutting of a position where the cutting blade overlaps an outer peripheral edge of the wafer is set smaller than an amount of the cutting fluid supplied during cutting of a position where the cutting blade does not overlap the outer peripheral edge of the wafer.

### BRIEF DESCRIPTION OF THE DRAWINGS

FIG. 1 is a perspective view of an exemplary configuration of a cutting apparatus according to a first embodiment;

FIG. 2 is a schematic perspective view of a wafer to be processed by the cutting apparatus illustrated in FIG. 1;

FIG. 3 is a cross-sectional view taken along the line III-III in FIG. 2;

FIG. 4 is a side view of a cutting unit of the cutting apparatus illustrated in FIG. 1;

FIG. 5 is a schematic front view illustrating a main part of the cutting unit illustrated in FIG. 4;

FIG. 6 is a schematic cross-sectional view of a state in which a holding table sucks and holds the wafer in a wafer processing method according to the first embodiment;

FIG. 7 is a schematic plan view illustrating a state in which an outer peripheral edge of the wafer held on the holding table is located at a position separated from the cutting unit, in an X-axis direction, in the wafer processing method according to the first embodiment;

FIG. 8 is a schematic plan view illustrating a state in which the holding table illustrated in FIG. 7 is brought closer to the cutting unit and the cutting blade is cut into the outer peripheral edge of the wafer, in the wafer processing method according to the first embodiment;

FIG. 9 is a schematic front view illustrating a main part of the cutting unit illustrated in FIG. 8, partially in a cross section;

FIG. 10 is a schematic front view illustrating a modification of the main part of the cutting unit illustrated in FIG. 9, partially in a cross section;

FIG. 11 is a schematic plan view illustrating a state in which the holding table illustrated in FIG. 8 is located at a position separated in the X-axis direction, from the cutting unit moved in a Y-axis direction, in the wafer processing method according to the first embodiment;

FIG. 12 is a schematic plan view illustrating a state in which the cutting blade illustrated in FIG. 11 is cut into the wafer on an inner peripheral side relative to the outer peripheral edge, in the wafer processing method according to the first embodiment; and

FIG. 13 is a schematic front view illustrating a main part of the cutting unit illustrated in FIG. 12, partially in a cross section.

### DETAILED DESCRIPTION OF THE PREFERRED EMBODIMENTS

Embodiments for carrying out the present disclosure (embodiments) will be described in detail with reference to the drawings. It is noted that the present invention is not limited to the contents described in the following embodiments. In addition, component elements described below include those that are readily conceivable by those skilled in the art and those that are substantially equivalent. Furthermore, configurations described below can be appropriately combined. Still furthermore, various omissions, substitutions, or modifications of the configurations can be made without departing from the gist of the present invention.

### First Embodiment

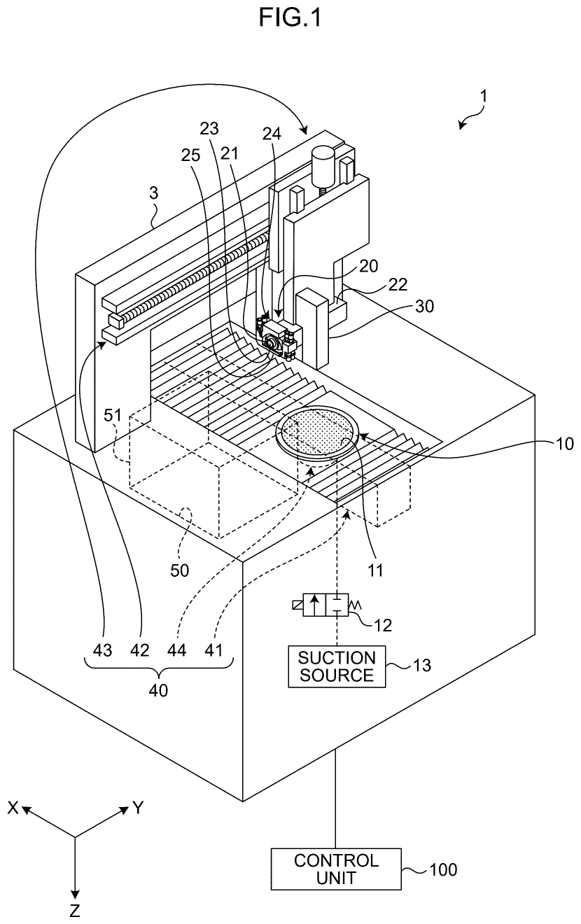

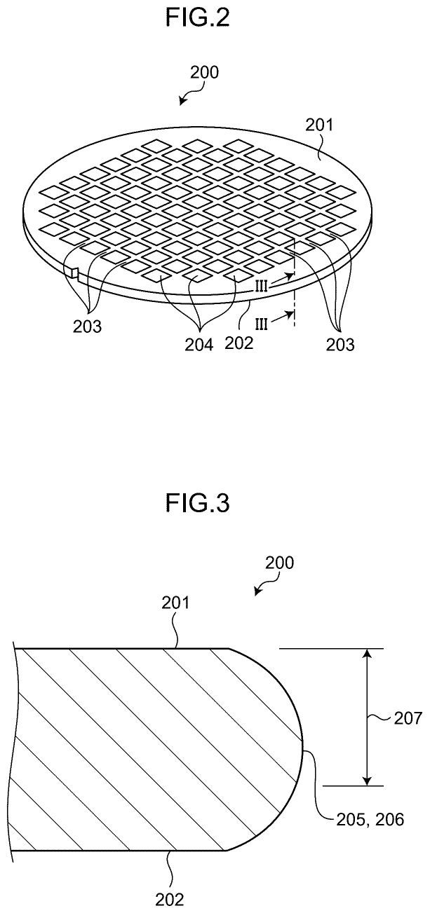

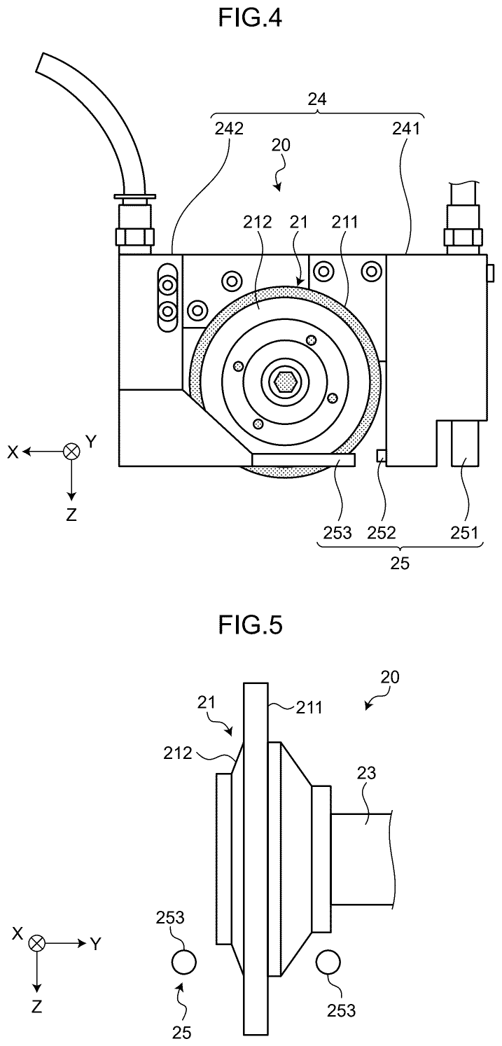

A cutting apparatus according to a first embodiment of the present disclosure will be described with reference to the drawings. FIG. 1 is a perspective view of an exemplary configuration of the cutting apparatus according to the first embodiment. FIG. 2 is a schematic perspective view of a wafer to be processed by the cutting apparatus illustrated in FIG. 1. FIG. 3 is a cross-sectional view taken along the line III-III in FIG. 2. FIG. 4 is a side view of a cutting unit of the cutting apparatus illustrated in FIG. 1. FIG. 5 is a schematic front view illustrating a main part of the cutting unit illustrated in FIG. 4.

### Wafer

The cutting apparatus 1 according to the first embodiment is a processing apparatus that cuts the wafer 200 illustrated in FIG. 2. In the first embodiment, the wafer 200 is a semiconductor wafer, an optical device wafer, or the like containing silicon, sapphire, gallium nitride, gallium arsenide, or the like as a base material. As illustrated in FIG. 2, the wafer 200 is formed in a disk shape having a circular front surface 201 (corresponding to a first surface) and a circular back surface 202 (second surface) that is on a back side of the front surface 201 and parallel with the front surface 201.

In the wafer 200, devices 204 are formed in areas divided in a lattice shape by a plurality of division lines 203 formed into a lattice pattern on the front surface 201. The devices 204 are each, for example, an integrated circuit such as an integrated circuit (IC) or a large scale integration (LSI), an image sensor such as a charge coupled device (CCD) or a complementary metal oxide semiconductor (CMOS), or a memory (semiconductor storage device).

In addition, as illustrated in FIG. 3, the wafer 200 has an outer periphery where a chamfered portion 205 is formed. The chamfered portion 205 is formed from the front surface 201 to the back surface 202, and has an arcuate cross section so that the center in a thickness direction is positioned on the outermost peripheral side. Note that the chamfered portion 205 has an outer surface that is an outer peripheral edge 206 of the wafer 200. In the wafer 200, the formation of the chamfered portion 205 sets the diameters of the front surface 201 and the back surface 202 smaller than a maximum outer diameter (the diameter at the center in the thickness direction) of the wafer 200.

After an outer edge portion is removed from the outer peripheral edge 206 by a depth 207 exceeding a predetermined thickness over the entire circumference from a side of the front surface 201, the wafer 200 is reduced in thickness to a predetermined thickness by grinding the back surface 202 or the like. The wafer 200 is then divided into individual devices 204 along the division lines 203. Note that in the first embodiment, the depth 207 is a depth that extends below the center in the thickness direction from the front surface 201 to the back surface 202.

### Cutting Apparatus

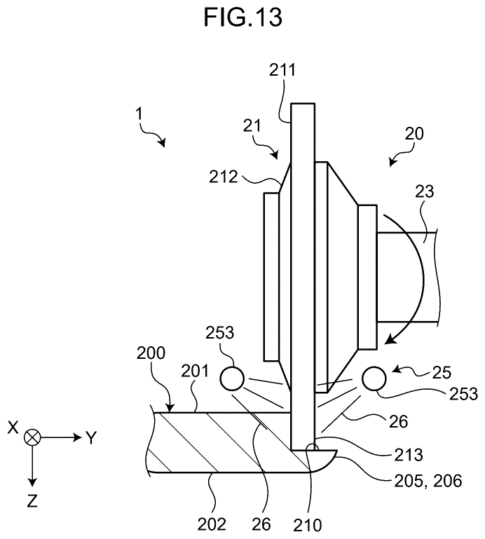

The cutting apparatus 1 illustrated in FIG. 1 is a processing apparatus that holds the wafer 200 on a holding table 10, cuts the outer peripheral edge 206 of the wafer 200 with a cutting blade 21, and forms an annular groove 210 (illustrated in FIG. 13) having a predetermined width and a depth 207 exceeding a predetermined thickness over the entire circumference from a side of the front surface 201, in an outer edge portion of the wafer 200 including the outer peripheral edge 206. As illustrated in FIG. 1, the cutting apparatus 1 includes the holding table 10 (corresponding to an attraction table) that sucks and holds the wafer 200 by a holding surface 11, a cutting unit 20 that cuts the wafer 200 held on the holding table 10 with the cutting blade 21, an imaging unit 30 that captures an image of the wafer 200 held on the holding table 10, and a control unit 100.

In addition, as illustrated in FIG. 1, the cutting apparatus 1 includes a moving unit 40 that moves the cutting unit 20 relative to the wafer 200 held on the holding table 10. The moving unit 40 includes an X-axis moving unit 41 for processing feed of the holding table 10 in an X-axis direction parallel with a horizontal direction, a Y-axis moving unit 42 for indexing feed of the cutting unit 20 in a Y-axis direction parallel with the horizontal direction and orthogonal to the X-axis direction, a Z-axis moving unit 43 for cutting feed of the cutting unit 20 in a Z-axis direction parallel with a vertical direction orthogonal to both the X-axis direction and the Y-axis direction, and a rotationally moving unit 44 that rotates the holding table 10 about an axis parallel with the Z-axis direction.

The X-axis moving unit 41 moves the holding table 10 in the X-axis direction being a processing feed direction, for processing feed of the holding table 10 and the cutting unit 20 relatively in the X-axis direction. The Y-axis moving unit 42 moves the cutting unit 20 in the Y-axis direction being an indexing feed direction, for indexing feed of the holding table 10 and the cutting unit 20 relatively in the Y-axis direction. The Z-axis moving unit 43 moves the cutting unit 20 in the Z-axis direction being a cutting feed direction, for cutting feed of the holding table 10 and the cutting unit 20 relatively in the Z-axis direction.

Each of the X-axis moving unit 41, the Y-axis moving unit 42, and the Z-axis moving unit 43 includes a known ball screw that is rotatably provided about an axis, a known motor that rotates the ball screw about the axis, and a known guide rail that movably supports the holding table 10 or the cutting unit 20 in the X-axis direction, the Y-axis direction, or the Z-axis direction.

The holding table 10 has a disk shape, and the holding surface 11 (corresponding to an attraction area) holding the wafer 200 is formed of porous ceramic or the like. In other words, the holding table 10 includes the holding surface 11. The holding surface 11 has an outer diameter that is equivalent to (in the first embodiment, equal to) the outer diameters of the front surface 201 and the back surface 202 of the wafer 200. In addition, the holding table 10 is provided movably in the X-axis direction over a processing area below the cutting unit 20 and a loading/unloading area separated from below the cutting unit 20 to load/unload the wafer 200, by the X-axis moving unit 41, and is rotatably provided about an axis parallel with the Z-axis direction, by the rotationally moving unit 44.

In the holding table 10, the holding surface 11 is connected to a suction source 13 via an on-off valve 12, and suction by the suction source 13 upon opening of the on-off valve 12 sucks and holds (also referred to as attracts) the wafer 200 mounted on the holding surface 11. In the first embodiment, the holding table 10 sucks and holds the back surface 202 of the wafer 200. In this way, the holding surface 11 sucks and holds the wafer 200. In the holding table 10, the outer diameter of the holding surface 11 attracting the wafer 200 is equivalent to the outer diameters of the front surface 201 and the back surface 202, and therefore, the holding surface 11 has a size that corresponds to that of the front surface 201 or the back surface 202 of the wafer 200.

The cutting unit 20 is cutting means that includes a spindle 23 to which the cutting blade 21 configured to cut the wafer 200 held on the holding table 10 is removably fixed. The cutting unit 20 is provided movably in the Y-axis direction by the Y-axis moving unit 42 and movably in the Z-axis direction by the Z-axis moving unit 43, with respect to the wafer 200 held on the holding table 10.

The cutting unit 20 is provided on a gate-shaped support frame 3 extending from an apparatus body, via the Y-axis moving unit 42, the Z-axis moving unit 43, and the like. In the cutting unit 20, the cutting blade 21 is allowed to be positioned at any position on the holding surface 11 of the holding table 10 by the Y-axis moving unit 42 and the Z-axis moving unit 43.

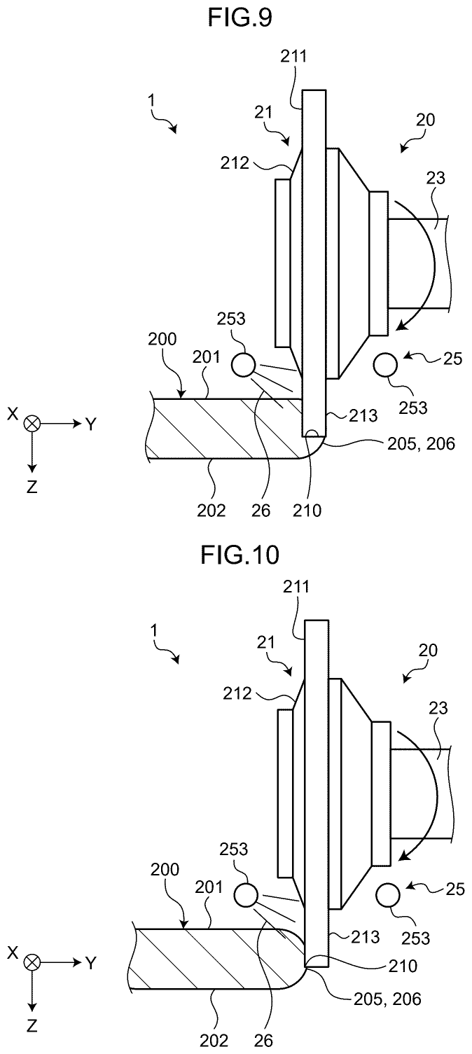

The cutting unit 20 includes the cutting blade 21, a spindle housing 22 that is provided movably in the Y-axis direction and the Z-axis direction by the Y-axis moving unit 42 and the Z-axis moving unit 43, the spindle 23 that is rotatably provided about an axis in the spindle housing 22, a spindle motor, which is not illustrated, rotating the spindle 23 about an axis, a blade cover 24 (illustrated in FIG. 4) that is attached to a leading end surface of the spindle housing 22 to cover at least above the cutting blade 21, and a cutting fluid supply nozzle 25 that is provided at a blade cover 24 to supply a cutting fluid 26 (illustrated in FIG. 9 etc.) to the cutting blade 21 and the like.

The cutting blade 21 is an extremely thin cutting abrasive having a substantially ring shape, and annularly cuts the wafer 200 along the outer periphery of the wafer 200 held on the holding table 10. In the first embodiment, as illustrated in FIG. 4, the cutting blade 21 includes an annular cutting edge 211 that cuts the wafer 200, and an annular base 212 that supports the cutting edge 211 at the outer edge and is removably mounted to the spindle 23.

The cutting edge 211 is made of an abrasive such as diamond and CBN (cubic boron nitride) and a bond material (bonding material) such as metal and resin, and is formed into a predetermined thickness. Note that in the present disclosure, the cutting blade 21 may be a so-called washer blade including only the cutting edge 211. Note that in the first embodiment, the cutting edge 211 has an edge that is formed flat in the Y-axis direction, as illustrated in FIG. 5.

The spindle housing 22 is movably supported in the Z-axis direction by the Z-axis moving unit 43, and is movably supported in the Y-axis direction by the Y-axis moving unit 42 via the Z-axis moving unit 43. The spindle housing 22 houses a portion excluding a leading end portion of the spindle 23, the spindle motor which is not illustrated, and the like, and rotatably supports the spindle 23 about the axis.

The leading end of the spindle 23 is configured to fix the cutting blade 21. The spindle 23 is rotated by the spindle motor which is not illustrated, and the leading end portion thereof protrudes from the leading end surface of the spindle housing 22. The leading end portion of the spindle 23 is gradually tapered toward the leading end to fix the cutting blade 21.

The blade cover 24 includes a fixed cover 241 that is fixed to the leading end surface of the spindle housing 22, and a sliding cover 242 that is provided to be slid by a cylinder, which is not illustrated, provided in the fixed cover 241, in the X-axis direction relative to the fixed cover 241. When the cutting unit 20 cuts the wafer 200, the sliding cover 242 is located at a closer position closer to the fixed cover 241, and when the cutting blade 21 is attached to/detached from the leading end portion of the spindle 23, the sliding cover 242 is located at an attachment/detachment position separated from the fixed cover 241 relative to the closer position.

The cutting fluid supply nozzle 25 is provided at the blade cover 24 to supply a cutting fluid 26 (in the first embodiment, pure water) to the cutting blade 21 and the like during cutting. As illustrated in FIG. 4, the cutting fluid supply nozzle 25 includes a spray nozzle 251, a shower nozzle 252, and a pair of blade coolers 253 (corresponding to a pair of nozzles).

The spray nozzle 251, from among the spray nozzle 251, the shower nozzle 252, and the blade coolers 253, is provided at the fixed cover 241 of the blade cover 24, and is provided on the frontmost side in the processing feed direction (relative movement direction of the cutting blade 21 in the X-axis direction relative to the wafer 200 when the cutting blade 21 cuts the wafer 200). The spray nozzle 251 injects the cutting fluid 26 downward from the fixed cover 241 of the blade cover 24 to supply the cutting fluid 26 to the wafer 200 while cutting.

The shower nozzle 252 is provided at the fixed cover 241 of the blade cover 24 and faces the edge of the cutting edge 211 of the cutting blade 21 in the X-axis direction. The shower nozzle 252 injects the cutting fluid 26 from the fixed cover 241 to the edge of the cutting edge 211 of the cutting blade 21 in the X-axis direction to supply the cutting fluid 26 to the cutting blade 21 during cutting.

The pair of blade coolers 253 are provided at the sliding cover 242 of the blade cover 24, extend in parallel with the X-axis direction, and spaced apart from each other in the Y-axis direction. As illustrated in FIG. 5, the pair of blade coolers 253 is arranged on both sides in a thickness direction of the cutting edge 211 of the cutting blade 21 with a lower end of the cutting edge 211 of the cutting blade 21 positioned therebetween.

Each of the pair of blade coolers 253 includes a cutting fluid injection hole, which is not illustrated, facing the lower end of the cutting edge 211 of the cutting blade 21. The blade cooler 253 injects the cutting fluid 26 from the cutting fluid injection hole to the lower end of the cutting edge 211 of the cutting blade 21 in the Y-axis direction to supply the cutting fluid 26 to the cutting blade 21 during cutting.

Furthermore, in the first embodiment, the cutting fluid 26 is supplied to each of the pair of blade coolers 253 via an on-off valve which is not illustrated. Opening and closing the on-off valves enable the pair of blade coolers 253 to inject the cutting fluid 26 independently of each other. One of the pair of blade coolers 253 is a first nozzle, and the other is a second nozzle.

The spindle 23 and the cutting blade 21 of the cutting unit 20 have axes that are set parallel with the Y-axis direction.

The imaging unit 30 is fixed to the cutting unit 20 so as to move integrally with the cutting unit 20. The imaging unit 30 includes an imaging element that captures an image of an area to be divided of the wafer 200 held on the holding table 10 before cutting. The imaging element is, for example, a charge-coupled device (CCD) imaging element or a complementary MOS (CMOS) imaging element. The imaging unit 30 captures an image of the wafer 200 held on the holding table 10 to obtain an image for, for example, alignment to align the wafer 200 and the cutting blade 21, and outputs the obtained image to the control unit 100.

In addition, the cutting apparatus 1 includes an X-axis direction position detection unit, which is not illustrated, for detecting a position of the holding table 10 in the X-axis direction, a Y-axis direction position detection unit, which is not illustrated, for detecting a position of the cutting unit 20 in the Y-axis direction, and a Z-axis direction position detection unit for detecting a position of the cutting unit 20 in the Z-axis direction. The X-axis direction position detection unit and the Y-axis direction position detection unit each include a linear scale parallel with the X-axis direction or the Y-axis direction and a reading head. The Z-axis direction position detection unit detects the position of the cutting unit 20 in the Z-axis direction with a motor pulse. The X-axis direction position detection unit, the Y-axis direction position detection unit, and the Z-axis direction position detection unit output the positions of the holding table 10 in the X-axis direction and the cutting unit 20 in the Y-axis direction or the Z-axis direction, to the control unit 100. Note that in the first embodiment, the positions of the component elements of the cutting apparatus 1 in the X-axis direction, the Y-axis direction, and the Z-axis direction are defined on the basis of predetermined reference positions which are not illustrated. Note that the reference position in the Z-axis direction is the position of the cutting unit 20 where the lower end of the cutting edge of the cutting blade 21 is located on the same plane as the holding surface 11.

In addition, the cutting apparatus 1 includes a cassette elevator 50 that mounts a cassette 51 storing the wafers 200 before and after cutting and moves the cassette 51 in the Z-axis direction, and a conveyance unit, which is not illustrated, conveying the wafers 200 between the cassette 51 and the holding table 10.

The control unit 100 controls the component elements of the cutting apparatus 1 to cause the cutting apparatus 1 to perform a processing operation on the wafer 200. Note that the control unit 100 is a computer that includes an arithmetic processing device including a microprocessor such as a central processing unit (CPU), a storage device including a memory such as a read only memory (ROM) or a random access memory (RAM), and an input/output interface device. The arithmetic processing device of the control unit 100 performs arithmetic processing according to a computer program stored in the storage device, and outputs a control signal for controlling the cutting apparatus 1, to each of the component elements of the cutting apparatus 1 via an input/output interface device.

The control unit 100 is connected to a display unit including a liquid crystal display device or the like displaying a state of a processing operation, an image, or the like, an input unit used when an operator registers processing content information or the like, and a notification unit. The input unit includes at least one of a touch screen provided on the display unit and an external input device such as a keyboard. The notification unit emits at least one of sound and light to give a notification to the operator.

### Wafer Processing Method

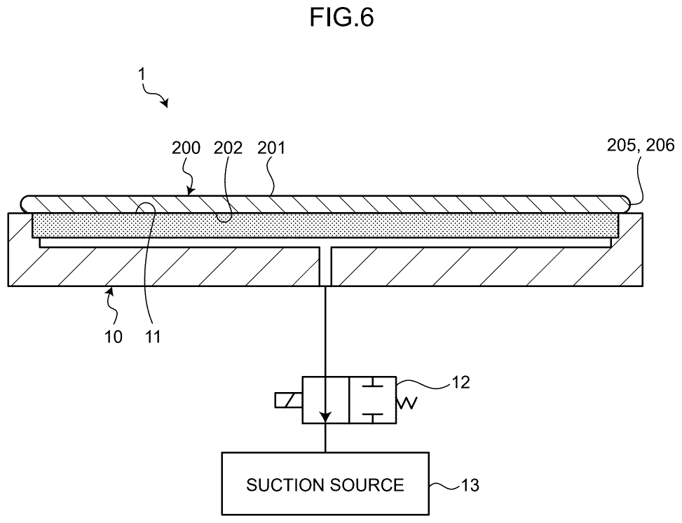

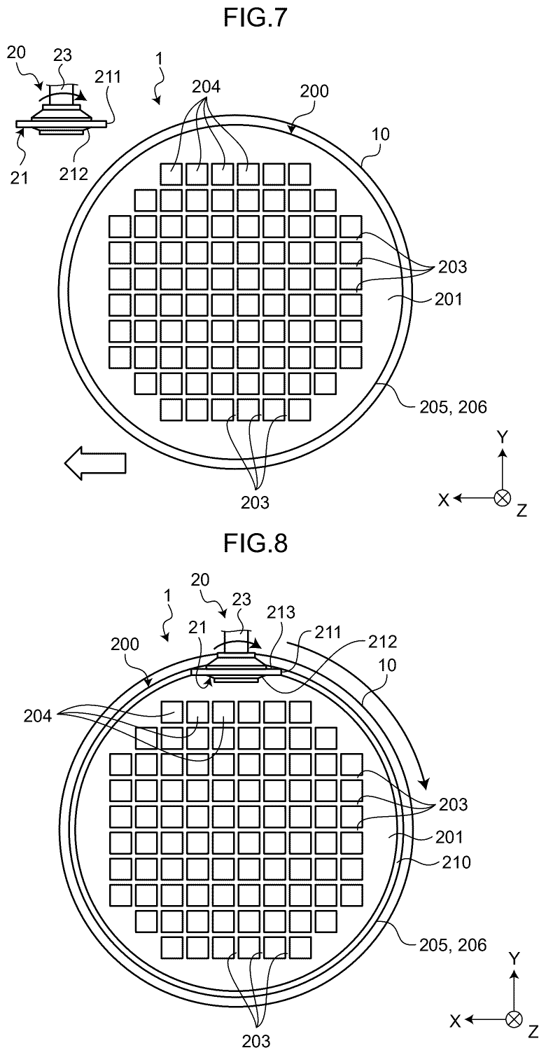

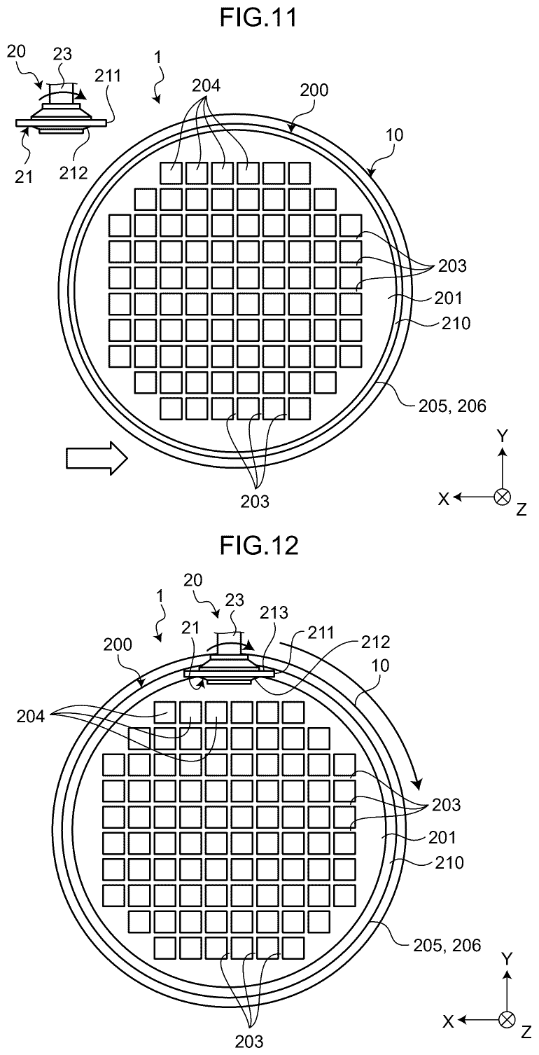

Next, a wafer processing method according to the first embodiment will be described. FIG. 6 is a schematic cross-sectional view of a state in which the holding table sucks and holds the wafer in the wafer processing method according to the first embodiment. FIG. 7 is a schematic plan view illustrating a state in which the outer peripheral edge of the wafer held on the holding table is located at a position separated from the cutting unit, in the X-axis direction, in the wafer processing method according to the first embodiment. FIG. 8 is a schematic plan view illustrating a state in which the holding table illustrated in FIG. 7 is brought closer to the cutting unit and the cutting blade is cut into the outer peripheral edge of the wafer, in the wafer processing method according to the first embodiment. FIG. 9 is a schematic front view illustrating a main part of the cutting unit illustrated in FIG. 8, partially in a cross section. FIG. 10 is a schematic front view illustrating a modification of the main part of the cutting unit illustrated in FIG. 9, partially in a cross section. FIG. 11 is a schematic plan view illustrating a state in which the holding table illustrated in FIG. 8 is located at a position separated in the X-axis direction, from the cutting unit moved in the Y-axis direction, in the wafer processing method according to the first embodiment. FIG. 12 is a schematic plan view illustrating a state in which the cutting blade illustrated in FIG. 11 is cut into the wafer on an inner peripheral side relative to the outer peripheral edge, in the wafer processing method according to the first embodiment. FIG. 13 is a schematic front view illustrating a main part of the cutting unit illustrated in FIG. 12, partially in a cross section.

The wafer processing method according to the first embodiment is a method in which the cutting apparatus 1 annularly cuts the wafer 200 along the outer periphery of the wafer 200 with the cutting blade 21 to form the annular groove 210 in the outer edge portion including the outer peripheral edge 206. The wafer processing method according to the first embodiment is a processing operation of the cutting apparatus 1 having the configurations described above as well.

In the wafer processing method according to the first embodiment, processing conditions are registered in the control unit 100 by the operator or the like, and the cassette 51 storing the wafers 200 before cutting is mounted on the cassette elevator 50. The wafer processing method according to the first embodiment is started by the cutting apparatus 1 when the control unit 100 of the cutting apparatus 1 receives an instruction from the operator to start the processing operation.

In the wafer processing method according to the first embodiment, when the cutting apparatus 1 starts the method, the control unit 100 controls the moving unit 40 to position the holding table 10 in the loading/unloading area, and controls the conveyance unit to take out a wafer 200 before cutting from the cassette 51 and mount the wafer 200 on the holding surface 11 of the holding table 10. In the wafer processing method according to the first embodiment, the cutting apparatus 1 is configured so that the control unit 100 opens the on-off valve 12 to suck and hold the back surface 202 of the wafer 200 on the holding surface 11 of the holding table 10, as illustrated in FIG. 6.

In the wafer processing method according to the first embodiment, the cutting apparatus 1 is configured so that the control unit 100 rotates the spindle 23 about the axis at a rotation speed defined in the processing conditions and supplies the cutting fluid 26 from the cutting fluid supply nozzle 25 to the cutting blade 21 and the like. In the wafer processing method according to the first embodiment, the cutting apparatus 1 is configured so that the control unit 100 controls the moving unit 40 to move the holding table 10 toward the processing area, the imaging unit 30 captures an image of the wafer 200, and alignment is performed on the basis of the image captured and obtained by the imaging unit 30.

In the wafer processing method according to the first embodiment, the cutting apparatus 1 is configured so that the control unit 100 controls the moving unit 40, the cutting unit 20, and the like to separate the cutting edge 211 of the cutting blade 21 rotating about an axis of the cutting unit 20 and part of the outer peripheral edge 206 of the wafer 200 held on the holding table 10 from each other in the X-axis direction as illustrated in FIG. 7. In addition, in the wafer processing method according to the first embodiment, the cutting apparatus 1 is configured so that the control unit 100 controls the moving unit 40, the cutting unit 20, and the like to arrange the lower end of the cutting edge 211 of the cutting blade 21 rotating about the axis, at a position where a distance from the front surface 201 of the wafer 200 held on the holding table 10 corresponds to the above depth 207. In addition, in the wafer processing method according to the first embodiment, the cutting apparatus 1 is configured so that the control unit 100 injects the cutting fluid 26 from only one blade cooler, of the pair of blade coolers 253, positioned on a side near the center of the wafer 200 held on the holding table 10 and stops injection of the cutting fluid 26 from the other blade cooler 253 that is positioned near the outer periphery of the wafer 200.

In the wafer processing method according to the first embodiment, the cutting apparatus 1 is configured so that the control unit 100 controls the moving unit 40 to move the holding table 10 in the X-axis direction being a direction in which the holding table 10 approaches the cutting unit 20, and controls the cutting edge 211 of the cutting blade 21 to cut into the outer edge portion including the outer peripheral edge 206 of the wafer 200 as illustrated in FIG. 8 and to rotate the holding table 10 about the axis. Note that, in the first embodiment, when the cutting edge 211 of the cutting blade 21 is cut into the outer edge portion of the wafer 200 first, the cutting edge 211 of the cutting blade 21 is located, as illustrated in FIG. 9, at a position where the entire thickness direction of the cutting edge 211 of the cutting blade 21 overlaps the base material of the wafer 200 in the Z-axis direction and where a side of the cutting edge 211 near the spindle housing 22, that is, an end surface 213 near the outer peripheral side of the wafer 200 overlaps the outer peripheral edge 206 of the wafer 200 in the Z-axis direction.

Furthermore, in the first embodiment, when the cutting edge 211 of the cutting blade 21 is cut into the outer edge portion of the wafer 200 first, the cutting fluid 26 is injected from only one blade cooler 253, of the pair of blade coolers 253, positioned on the side near the center of the wafer 200 held on the holding table 10 and injection of the cutting fluid 26 from the other blade cooler 253 that is positioned near the outer periphery of the wafer 200 is stopped, as illustrated in FIG. 9. Note that, in the present disclosure, when the cutting edge 211 of the cutting blade 21 is cut into the outer edge portion including the outer peripheral edge 206 of the wafer 200, the cutting edge 211 of the cutting blade 21 may be located at a position where a part of the thickness direction of the cutting edge 211 of the cutting blade 21 positioned near the center of the wafer 200 overlaps the base material of the wafer 200 in the Z-axis direction and where the other part of the thickness direction of the cutting edge 211 positioned near the outer periphery of the wafer 200 is positioned on an outer peripheral side of the wafer 200 relative to the outer peripheral edge 206 of the wafer 200, as illustrated in FIG. 10.

In the wafer processing method according to the first embodiment, the cutting apparatus 1 is configured so that when the holding table 10 rotates at least once about the axis, the control unit 100 controls the moving unit 40 to move the holding table 10 in the X-axis direction being a direction in which the holding table 10 is separated from the cutting unit 20 as illustrated in FIG. 11. Then, the annular groove 210 along the outer peripheral edge 206 of the wafer 200 is formed in the outer edge portion of the wafer 200 by removing the chamfered portion 205 including the outer peripheral edge 206 from the side of the front surface 201 by the depth 207. In this way, in the wafer processing method according to the first embodiment, the cutting apparatus 1 is configured so that during cutting of a position where the cutting edge 211 of the cutting blade 21 at least partially overlaps the outer peripheral edge 206 of the wafer 200 in the Z-axis direction, as illustrated in FIG. 9, the cutting fluid 26 is injected from only one blade cooler 253, of the pair of blade coolers 253, positioned on the side near the center of the wafer 200, and the cutting fluid 26 is supplied to the cutting blade 21 only from the one blade cooler 253 positioned near the center of the wafer 200.

In the wafer processing method according to the first embodiment, the cutting apparatus 1 is configured so that the control unit 100 controls the moving unit 40 to move the cutting unit 20, that is, the cutting edge 211 of the cutting blade 21 toward the center of the wafer 200 only in the Y-axis direction, by the thickness of the cutting edge 211 of the cutting blade 21. In the wafer processing method according to the first embodiment, the cutting apparatus 1 is configured so that the control unit 100 injects the cutting fluid 26 only from both blade coolers of the pair of blade coolers 253. In the wafer processing method according to the first embodiment, the cutting apparatus 1 is configured so that the control unit 100 controls the moving unit 40 to move the holding table 10 in the X-axis direction being a direction in which the holding table 10 approaches the cutting unit 20, and controls the cutting edge 211 of the cutting blade 21 to cut into the inner periphery side of the annular groove 210 of the wafer 200 as illustrated in FIG. 12 and to rotate the holding table 10 about the axis.

In the wafer processing method according to the first embodiment, the cutting apparatus 1 is configured so that when the holding table 10 rotates at least once about the axis, the control unit 100 controls the moving unit 40 to move the holding table 10 in the X-axis direction being a direction in which the holding table 10 is separated from the cutting unit 20. Then, the width of the annular groove 210 formed in the outer edge portion of the wafer 200 is increased by the thickness of the cutting edge 211 of the cutting blade 21. In this way, in the wafer processing method according to the first embodiment, the cutting apparatus 1 is configured so that during cutting of a position where the entire cutting edge 211 of the cutting blade 21 does not overlap the outer peripheral edge 206 of the wafer 200 in the Z-axis direction, that is, a position on an inner peripheral side relative to the outer peripheral edge 206, as illustrated in FIG. 13, the cutting fluid 26 is injected from both blade coolers 253 of the pair of blade coolers 253, and the cutting fluid 26 is supplied from both of the pair of blade coolers 253 to the cutting blade 21.

In the wafer processing method according to the first embodiment, the cutting apparatus 1 repeats an operation of moving the holding table 10 in the X-axis direction to cause the cutting edge 211 of the cutting blade 21 to cut into the wafer 200 and rotate around the wafer 200 at least once about the axis, until the width of the above annular groove 210 becomes a width defined in the processing conditions, and an operation of moving the holding table 10 from the cutting blade 21 in the X-axis direction for separation and then moving the cutting blade 21 only in the Y-axis direction. In this way, the outer edge portion including the outer peripheral edge 206 of the wafer 200 whose back surface 202 is sucked and held by the holding table 10 is cut with the cutting blade 21, and the annular groove 210 is formed.

As described above, in the wafer processing method according to the first embodiment, the cutting apparatus 1 cuts the wafer 200 annularly with the cutting blade 21 along the outer periphery of the wafer 200 while supplying the cutting fluid 26 to the wafer 200 and cuts the outer edge portion of the wafer 200 by changing the position of the cutting blade 21 in a radial direction of the wafer 200, and sets an amount of the cutting fluid 26 supplied during cutting of the position where the cutting edge 211 of the cutting blade 21 at least partially overlaps the outer peripheral edge 206 of the wafer 200 smaller than an amount of the cutting fluid 26 supplied during cutting of the position where the cutting blade 21 does not overlap the outer peripheral edge 206 of the wafer 200 (i.e., the position on the inner peripheral side relative to the outer peripheral edge 206).

In the wafer processing method according to the first embodiment, the cutting apparatus 1 is configured so that when the annular groove 210 having the depth 207 of desired and the predetermined width is formed in the outer edge portion including the outer peripheral edge 206 of the wafer 200, over the entire circumference of the wafer 200 along the outer peripheral edge 206, the control unit 100 controls the moving unit 40 to separate the cutting unit 20 from the wafer 200 held on the holding table 10, and then moves the holding table 10 to the loading/unloading area. In the wafer processing method according to the first embodiment, the cutting apparatus 1 stops suction and holding of the wafers 200 by the holding table 10 in the loading/unloading area, and causes the conveyance unit to convey the wafers 200 from the holding table 10 to the cassette 51.

In the wafer processing method according to the first embodiment, the cutting apparatus 1 sequentially cuts the wafers 200 in the cassette 51. In the wafer processing method according to the first embodiment, after cutting all the wafers 200 in the cassette 51, the cutting apparatus 1 finishes the wafer processing method, that is, the processing operation.

The wafer 200 is provided with the chamfered portion 205, and therefore, it is difficult to suck and hold the outer edge portion including the outer peripheral edge 206 by the holding table 10, it is apt to vibrate the outer edge portion being an area not sucked and held during cutting, and it tends to extremely deteriorate the processing quality when the cutting fluid 26 enters between the wafer 200 and the holding surface 11.

However, in the wafer processing method and the cutting apparatus 1 according to the first embodiment, the amount of the cutting fluid 26 supplied during the cutting the position where the cutting edge 211 of the cutting blade 21 overlaps the outer peripheral edge 206 of the wafer 200 is set smaller than the amount of the cutting fluid supplied during cutting of the position where the cutting blade 21 does not overlap the outer peripheral edge 206 of the wafer 200.

For this reason, the wafer processing method and the cutting apparatus 1 according to the first embodiment enables reduction in a possibility that the cutting fluid 26 enters on a side of the back surface 202 of the wafer 200 held on the holding table 10 during cutting and suppression of the amount of the entering cutting fluid 26, suppressing instability of the wafer 200 during cutting.

Therefore, the wafer processing method and the cutting apparatus 1 according to the first embodiment have an effect of suppressing the deterioration in processing quality.

In addition, the wafer processing method and the cutting apparatus 1 according to the first embodiment uses the holding table 10 with the holding surface 11 having a size corresponding to that of the back surface 202 to suck and hold the back surface 202 for cutting the wafer 200, and therefore, the wafer 200 is reliably attracted to the holding surface 11 of the holding table 10.

In the embodiments, in causing the cutting edge 211 of the cutting blade 21 to cut into the wafer 200 and in separating the cutting blade 21 from the wafer 200, the holding table 10 is moved in the X-axis direction parallel with the horizontal direction. However, in the present disclosure, in causing the cutting edge 211 of the cutting blade 21 to cut into the wafer 200 and in separating the cutting blade 21 from the wafer 200, the cutting blade 21 may be moved in the Z-axis direction.

In other words, in the present disclosure, so-called chopper cut may be used to cause the cutting blade 21 to cut into the wafer 200, raise the cutting blade 21 cut into the wafer 200, and separate the cutting blade 21 from the wafer 200. In the present invention, the front surface 201 being the first surface of the wafer 200 may be sucked and held on the holding surface 11 of the holding table 10.

According to the present disclosure, it is possible to effectively suppress deterioration in processing quality.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wafer processing method for annularly cutting a wafer along an outer periphery of the wafer with a cutting blade, the method comprising
annularly cutting the wafer with the cutting blade along the outer periphery of the wafer while supplying a cutting fluid to the wafer, and cutting the wafer by changing a position of the cutting blade in a radial direction of the wafer, wherein
an amount of the cutting fluid supplied during cutting of a position where the cutting blade overlaps an outer peripheral edge of the wafer is set smaller than an amount of the cutting fluid supplied during cutting of a position where the cutting blade does not overlap the outer peripheral edge of the wafer.

2. The wafer processing method according to claim 1, wherein
the cutting fluid is injected toward the cutting blade from a pair of nozzles arranged on both sides in a thickness direction of the cutting blade and supplied to the wafer via the cutting blade,
the cutting fluid is injected only from a nozzle, of the pair of nozzles, positioned on a side near a center of the wafer, during cutting of the position where the cutting blade overlaps the outer peripheral edge of the wafer, and
the cutting fluid is injected from both of the pair of nozzles, during cutting of the position where the cutting blade does not overlap the outer peripheral edge of the wafer.

3. The wafer processing method according to claim 1, wherein
the wafer includes a first surface, a second surface that is on a back side of the first surface, and a chamfered portion that is formed on an outer periphery, the first surface and the second surface having diameters set smaller than a maximum outer diameter of the wafer due to the chamfered portion, and
the wafer is cut with the cutting blade with a first surface side or a second surface side attracted by an attraction table having an attraction area corresponding to the first surface or the second surface.

4. A cutting apparatus comprising:
a holding table that holds a wafer;
a cutting blade that annularly cuts the wafer along an outer periphery of the wafer held by the holding table; and
a cutting fluid supply nozzle that supplies a cutting fluid to the wafer to be cut with the cutting blade, wherein
the wafer held by the holding table is annularly cut along the outer periphery of the wafer with the cutting blade while supplying the cutting fluid to the wafer from the cutting fluid supply nozzle, and the wafer is cut by changing a position of the cutting blade in a radial direction of the wafer, and
an amount of the cutting fluid supplied during cutting of a position where the cutting blade overlaps an outer peripheral edge of the wafer is set smaller than an amount of the cutting fluid supplied during cutting of a position where the cutting blade does not overlap the outer peripheral edge of the wafer.

5. The cutting apparatus according to claim 4, wherein
the cutting fluid supply nozzle includes a first nozzle and a second nozzle that are arranged on both sides in a thickness direction of the cutting blade,
the cutting fluid is supplied only from a nozzle, of the first nozzle and the second nozzle, positioned on a side near a center of the wafer, during cutting of the position where the cutting blade overlaps the outer peripheral edge of the wafer, and
the cutting fluid is supplied from both the first nozzle and the second nozzle during cutting of the position where the cutting blade does not overlap the outer peripheral edge of the wafer.

6. The cutting apparatus according to claim 4, wherein
the wafer includes a first surface, a second surface that is on a back side of the first surface, and a chamfered portion that is formed on an outer periphery, the first surface and the second surface having diameters set smaller than an outer diameter of the wafer due to the chamfered portion, and
the holding table has an attraction area corresponding to the first surface or the second surface of the wafer.
